(19) United States
(12) Patent Application Publication
(10) Pub. No.: US 2026/0117385 A1
(43) Pub. Date: Apr. 30, 2026

(54) SUBSTRATE PROCESSING APPARATUS AND SUBSTRATE PROCESSING METHOD

(71) Applicant: Tokyo Electron Limited, Tokyo (JP)

(72) Inventor: Manabu HONMA, Iwate (JP)

(21) Appl. No.: 19/365,722

(22) Filed: Oct. 22, 2025

(30) Foreign Application Priority Data
Oct. 24, 2024 (JP) 2024-187186

(51) Int. Cl. C23C 16/46; C23C 16/455; C23C 16/458

(52) U.S. Cl. CPC C23C 16/46; C23C 16/45525; C23C 16/4584

(57) ABSTRACT

A substrate processing apparatus includes a processing container, a substrate support that is provided inside the processing container and supports a substrate, and a heating unit that heats the substrate supported by the substrate support. The heating unit includes a heater wire that transmits radiant heat to a periphery during heating, and a lens member that is provided at a position adjacent to the heater wire. The lens member is disposed between the substrate support and the heater wire to direct radiant heat toward a direction in which the substrate is located, and/or disposed between the processing container and the heater wire to direct radiant heat in a direction perpendicular to a surface of the processing container.

### CROSS REFERENCES TO RELATED APPLICATIONS

This application is based on and claims priority from Japanese Patent Application No. 2024-187186, filed on Oct. 24, 2024, with the Japan Patent Office, the disclosure of which is incorporated herein in its entirety by reference.

### TECHNICAL FIELD

The present disclosure relates to a substrate processing apparatus and a substrate processing method.

### BACKGROUND

Japanese Patent No. 6464785 discloses a substrate processing apparatus (e.g., a heat treatment apparatus), which includes a rotary table for supporting a plurality of substrates in the inside of a vacuum container, and forms a film on the surface of each substrate by supplying a processing gas while rotating (e.g., revolving) the rotary table. This substrate processing apparatus is provided, on the backside of the rotary table, with a heating unit (e.g., a heater) for heating each substrate. The heating unit is configured by concentrically arranging a plurality of heater elements such as carbon wire heaters.

### SUMMARY

According to an aspect of the present disclosure, a substrate processing apparatus includes a processing container, a substrate support that is provided inside the processing container and to supports a substrate, and a heating unit that heats the substrate supported by the substrate support. The heating unit includes a heater wire that transmits radiant heat to a periphery during heating, and a lens member that is provided at a position adjacent to the heater wire. The lens member is disposed between the substrate support and the heater wire to direct radiant heat toward a direction in which the substrate is located, and/or disposed between the processing container and the heater wire to direct radiant heat in a direction perpendicular to a surface of the processing container.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view schematically illustrating a substrate processing apparatus according to the present embodiment.

FIG. 2 is a plan view schematically illustrating the inside of a processing container of the substrate processing apparatus.

FIG. 3 is a partial cross-sectional view of the processing container along the concentric arrangement of a source gas nozzle, a first separation gas nozzle, and a reaction gas nozzle of a rotary table.

FIG. 4 is a cross-sectional perspective view illustrating the rotary table and a heating unit.

FIG. 5 is an enlarged cross-sectional view illustrating a configuration of the rotary table at the outer peripheral side.

FIG. 6 is an enlarged cross-sectional view illustrating a lens member.

FIG. 7 is a flowchart illustrating a processing flow of a substrate processing method.

FIG. 8 is a cross-sectional view schematically illustrating a heating unit according to a first modification.

FIG. 9 is an enlarged view illustrating a heater wire and a lens member according to a second modification.

FIG. 10 is an enlarged view illustrating a heater wire and a lens member according to a third modification.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for carrying out the present disclosure will be described with reference to the drawings. In each drawing, the same reference numerals may be given to the same components, and redundant descriptions may be omitted.

### <Configuration of Substrate Processing Apparatus 100>

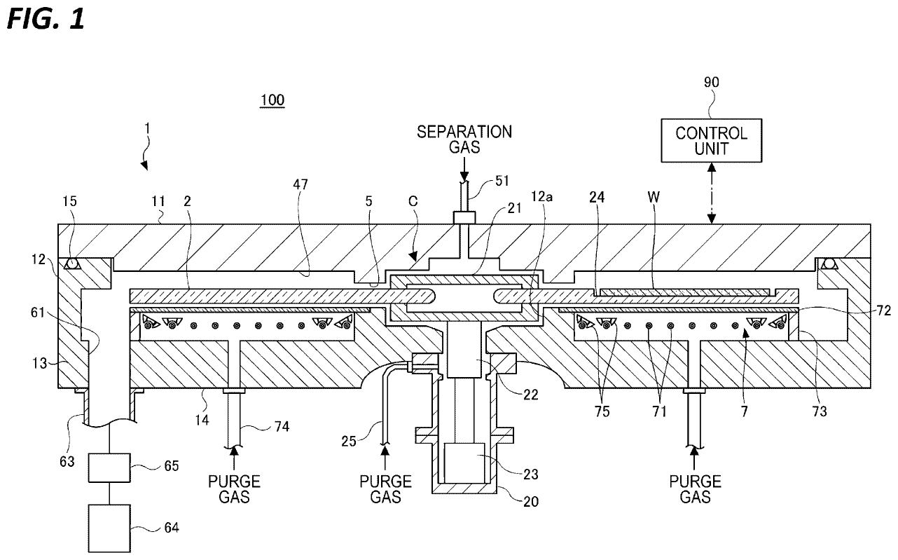

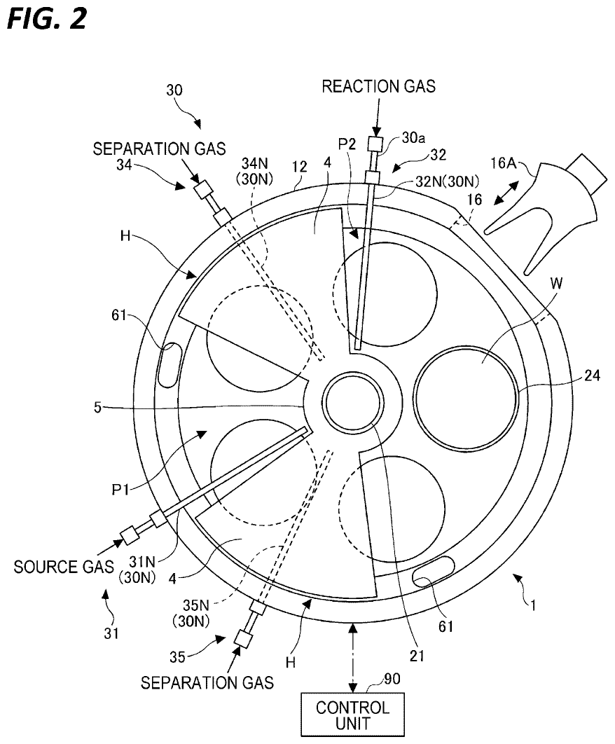

As illustrated in FIGS. 1 and 2, a substrate processing apparatus 100 according to an embodiment performs a substrate processing of forming a film on the surface of a substrate W by atomic layer deposition (ALD) or molecular layer deposition (MLD). The substrate processing apparatus 100 includes a processing container 1 that accommodates the substrate W therein, and a rotary table 2 that is a substrate support for rotatably supporting the substrate W in the inside of the processing container 1.

The processing container 1 is formed in a flat cylindrical shape having a processing chamber therein. For example, the processing container 1 is configured by assembling a container body 12 having an opening at the upper surface thereof with a ceiling plate 11 that closes the opening of the container body 12. In FIG. 2, for convenience of description, illustration of the ceiling plate 11 is omitted.

The container body 12 has a disc-shaped bottom portion 14, and a side portion 13 protruding vertically upward from the outer edge of the bottom portion 14. The upper end of the side portion 13 of the container body 12 and the ceiling plate 11 are airtightly fixed via a sealing member 15 such as an O-ring.

The rotary table 2 is formed in an annular shape, and an inner peripheral portion thereof is fixed to a cylindrical core 21. The rotary table 2 is formed of quartz having transparency. The core 21 is fixed to the upper end of a rotary shaft 22 extending in the vertical direction. The rotary shaft 22 penetrates the bottom portion 14 of the processing container 1, and the lower end thereof is held by a driving unit 23. The driving unit 23 rotates the rotary shaft 22 about the axis. Thus, the rotary table 2 rotates about the center of the processing container 1 as a rotation center via the rotary shaft 22 and the core 21.

The rotary shaft 22 and the driving unit 23 are accommodated in a cylindrical case body 20 having an opening at the upper surface thereof. The case body 20 is airtightly fixed to the bottom portion 14 of the processing container 1 via a flange portion at the upper end thereof. Therefore, an internal space of the case body 20 is isolated from the outside of the case body 20, and is in communication with the processing chamber of the processing container 1.

As illustrated in FIG. 2, a plurality of (e.g., five in FIG. 2) circular placement recesses 24 (e.g., a placement portion) each capable of placing the substrate W are provided on the upper surface of the rotary table 2 in the rotational direction of the rotary table 2. As the substrate W on which a substrate processing is performed, a semiconductor wafer such as a silicon semiconductor, compound semiconductor, or oxide semiconductor may be used. The substrate W may have recesses such as trenches and vias on the surface thereof.

The placement recess 24 has an inner diameter slightly larger than the diameter of the substrate W (e.g., 300 mm) and a depth approximately equal to the thickness of the substrate W. Thus, in a state where the substrate W is placed in the placement recess 24, the upper surface of the rotary table 2 in a region where the substrate W is not placed and the upper surface of the substrate W are approximately at the same height.

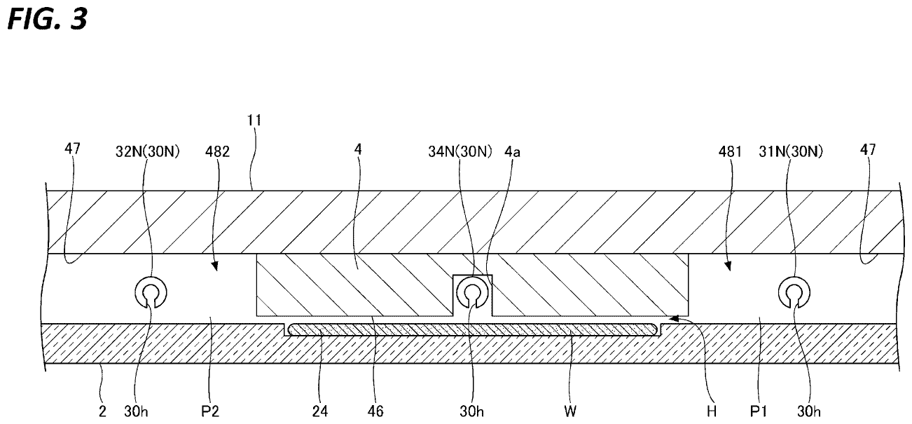

Then, the substrate processing apparatus 100 includes a gas supply 30 for supplying gases to the inside of the processing container 1. The gas supply 30 includes a plurality of gas nozzles 30N, which are formed of, for example, quartz, and extend linearly. Each of the gas nozzles 30N has an introduction port 30a serving as a base end fixed to the side portion 13 of the processing container 1, and extends to the vicinity of the center in the radial direction of the processing container 1. The gas nozzles 30N respectively extend parallel to the upper surface of the rotary table 2 in the processing chamber. A plurality of gas discharge holes 30h, which open vertically downward toward the rotary table 2, are formed in the respective gas nozzles 30N (see, e.g., FIG. 3). The gas discharge holes 30h are arranged at equal intervals in the axial direction (e.g., the radial direction of the processing container 1).

The gas supply 30 includes a source gas supply 31 for supplying a source gas, a reaction gas supply 32 for supplying a reaction gas, and a first separation gas supply 34 and a second separation gas supply 35 for supplying a separation gas. Further, the source gas supply 31, the reaction gas supply 32, the first separation gas supply 34, and the second separation gas supply 35 each include one source gas nozzle 31N, one reaction gas nozzle 32N, one first separation gas nozzle 34N, and one second separation gas nozzle 35N. However, the number of gas nozzles 30N is not particularly limited, and a plurality may be provided. In the processing container 1 of the illustrated example, the second separation gas nozzle 35N, the source gas nozzle 31N, the first separation gas nozzle 34N, and the reaction gas nozzle 32N are sequentially arranged in a clockwise direction from a transport port 16 provided in the side portion 13.

The source gas supply 31 connects a source gas supply path to the introduction port 30a of the source gas nozzle 31N protruding to the outside of the processing container 1. Although not illustrated, the source gas supply path is provided with a source gas supply source, an on-off valve, and a flow rate regulator to supply a source gas to the source gas nozzle 31N. The source gas supplied to the processing chamber by the source gas supply 31 may be appropriately selected according to the type of film to be formed on the substrate W. For example, when forming a titanium film on the substrate W, a titanium-containing gas is supplied as the source gas.

The reaction gas supply 32 connects a reaction gas supply path to the introduction port 30a of the reaction gas nozzle 32N protruding to the outside of the processing container 1. Although not illustrated, the reaction gas supply path is provided with a reaction gas supply source, an on-off valve, and a flow rate regulator to supply a reaction gas to the reaction gas nozzle 32N. The reaction gas supplied to the processing chamber by the reaction gas supply 32 may also be appropriately selected according to the type of film to be formed on the substrate W. For example, when oxidizing the titanium film attached to the substrate W, an oxygen-containing gas is supplied as the reaction gas.

The first separation gas supply 34 connects a separation gas supply path to the introduction port 30a of the first separation gas nozzle 34N protruding to the outside of the processing container 1. Although not illustrated, the first separation gas supply path is provided with a separation gas supply source, an on-off valve, and a flow rate regulator to supply a separation gas to the first separation gas nozzle 34N. The second separation gas supply 35 connects a separation gas supply path to the introduction port 30a of the second separation gas nozzle 35N protruding to the outside of the processing container 1. Although not illustrated, the second separation gas supply path is provided with a separation gas supply source, an on-off valve, and a flow rate regulator to supply a separation gas to the second separation gas nozzle 35N. The separation gases supplied by the first separation gas supply 34 and the second separation gas supply 35 are appropriately selected from among noble gases such as argon (Ar) and helium (He), and inert gases such as nitrogen (N₂) gas.

Further, the processing container 1 includes, inside thereof, two convex portions 4 arranged in the circumferential direction. Each convex portion 4 has a substantially fan-shaped planar shape cut along an arc, and in the embodiment, the inner arc thereof is connected to a protrusion 5 to be described later, and the outer arc thereof is disposed along the inner peripheral surface of the side portion 13 of the processing container 1.

As illustrated in FIG. 3, the convex portion 4 is attached to the lower surface of the ceiling plate 11. Therefore, there are, inside the processing container 1, a flat low ceiling surface 46, which is the lower surface of the convex portion 4, and a ceiling surface 47, which is located on both circumferential sides of the ceiling surface 46 and is higher than the ceiling surface 46.

A groove 4a is formed in the convex portion 4 to extend in the radial direction of the rotary table 2. The first separation gas nozzle 34N is accommodated in the groove 4a. Similarly, another groove 4a is formed in the other convex portion 4, and the second separation gas nozzle 35N is accommodated in the other groove 4a (see, e.g., FIG. 2).

As illustrated in FIG. 3, the source gas nozzle 31N is provided in a space 481 on the right side of the convex portion 4 (e.g., the space vertically below the high ceiling surface 47). The reaction gas nozzle 32N is provided in a space 482 on the left side of the convex portion 4 (e.g., the space vertically below the high ceiling surface 47). These gas nozzles 30N are provided in the vicinity of the substrate W while being spaced apart from the ceiling surface 47.

Meanwhile, the low ceiling surface 46 forms, with respect to the rotary table 2, a narrow separation space H. Since the volume of the separation space H is smaller than the volume of the spaces 481 and 482, when nitrogen gas (e.g., a separation gas) is supplied from the first separation gas nozzle 34N, the pressure in the separation space H may be made higher than the pressure in the spaces 481 and 482 by the nitrogen gas. Thus, the separation space H creates a pressure barrier between the spaces 481 and 482. Moreover, the nitrogen gas flowing out from the separation space H to the spaces 481 and 482 acts as a counterflow between the source gas and the reaction gas. Accordingly, the source gas and the reaction gas are separated by the separation space H, and mutual mixing and reaction thereof are prevented.

Referring back to FIGS. 1 and 2, the protrusion 5 provided on the lower surface of the ceiling plate 11 surrounds the outer periphery of the core 21 that serves to fix the rotary table 2. The protrusion 5 is continuous with a rotation center side portion of the convex portion 4, and the lower surface thereof is set to the same height as the ceiling surface 46.

Further, exhaust ports 61 are formed respectively between the rotary table 2 and the side portion 13 of the container body 12. Each exhaust port 61 is connected to an exhaust pipe 63, and the exhaust pipe 63 is connected to a vacuum pump 64, which is an evacuation tool, via a pressure regulator 65.

A heating unit 7 is provided in a space between the bottom portion 14 of the processing container 1 and the rotary table 2 to heat each substrate W placed on the rotary table 2. The heating unit 7 heats each substrate W so that the substrate reaches a target temperature set in a substrate processing recipe. The target temperature is not particularly limited, but may be, for example, in the range of 650° C. to 800° C. In particular, in a case where a carbon wire heater is applied as a heater wire 71 of the heating unit 7, a large amount of radiant heat is emitted by setting the temperature to 700° C. or higher. A configuration of the heating unit 7 will be described in detail later.

Further, a portion of the bottom portion 14, which is closer to the rotation center than the space where the heating unit 7 is disposed, is provided with a protrusion 12a, which protrudes so as to approach the core 21 at the center of the lower surface of the rotary table 2. A narrow space is formed between the protrusion 12a and the core 21. Further, the gap between the rotary shaft 22 and the inner peripheral surface of a through-hole of the bottom portion 14 through which the rotary shaft 22 passes is made narrow. The narrow space and gap are in communication with the case body 20.

Then, the case body 20 is provided with a purge gas supply pipe 25, which supplies a purge gas (e.g., the same gas as the separation gas supplied from the first separation gas nozzle 34N) into the narrow space. Furthermore, a plurality of purge gas supply pipes 74 for purging the space where the heating unit 7 is disposed are provided in the bottom portion 14 below the heating unit 7 at appropriate intervals in the circumferential direction.

When a purge gas is supplied from the purge gas supply pipe 25, the purge gas flows through the gap between the rotary shaft 22 and the inner peripheral surface of the through-hole through which the rotary shaft 22 passes and through the gap between the protrusion 12a and the core 21, and then flows through the space between the rotary table 2 and the heating unit 7, and is exhausted from the exhaust ports 61. Further, when a purge gas is supplied from the purge gas supply pipes 74, the purge gas flows out through a gap (not illustrated) from the space where the heating unit 7 is accommodated and is exhausted from the exhaust ports 61. By these flows of purge gas, it is possible to prevent mixing of the source gas and the reaction gas through the space below the center of the processing container 1 and the space below the rotary table 2.

Further, a separation gas supply pipe 51 is connected to the center of the ceiling plate 11 of the processing container 1. The separation gas supply pipe 51 supplies a separation gas (e.g., the same gas as the separation gas supplied from the first separation gas nozzle 34N) into a space between the ceiling plate 11 and the core 21. The separation gas supplied into this space flows along the surface of the rotary table 2 through the narrow space between the protrusion 5 and the rotary table 2. The space near the protrusion 5 and the center of the rotary table 2 is maintained at a high pressure by the separation gas. Accordingly, mixing of the source gas and the reaction gas through the space near the center is prevented.

Further, as illustrated in FIG. 2, the transport port 16 is formed in the sidewall of the processing container 1 to transfer the substrate W between an external transport robot 16A and the rotary table 2. The transport port 16 is opened or closed by a gate valve (not illustrated). The substrate processing apparatus 100 receives or transfers the substrate W from or to the transport robot 16A by positioning each placement recess 24 of the rotary table 2 so as to face the transport port 16. Therefore, although not illustrated, the substrate processing apparatus 100 includes, at a position adjacent to the transport port 16 below the rotary table 2, lift pins that pass through the placement recess 24 to lift the substrate W from the backside, as well as an elevating mechanism.

The substrate processing apparatus 100 includes a control unit 90 that controls the operation of the entire apparatus. The control unit 90 is a computer having a processor, a memory, an input/output interface, and communication interface. The processor 91 is one or a combination of a central processing unit (CPU), a graphics processing unit (GPU), an application specific integrated circuit (ASIC), a field-programmable gate array (FPGA), and a circuit including a plurality of discrete semiconductors. The memory includes a main storage device and an auxiliary storage device. The memory may be configured by appropriately combining a volatile memory and non-volatile memory (e.g., a hard disk, a flash memory, and a digital versatile disc (DVD)). In other words, the control unit 90 of the present disclosure is an electronic circuit having a CPU, GPU, ASIC, and FPGA, which executes various control operations described in this specification by executing instruction codes stored in the memory or by being designed as a circuit for a specific purpose.

For example, in a substrate processing, the control unit 90 controls the heating unit 7 to heat each substrate W while evacuating the inside of the processing container 1 with the vacuum pump 64. Furthermore, the control unit 90 controls the rotary table 2 to rotate (revolve) each substrate W, and also controls the gas supply 30 to supply a source gas, a reaction gas, a separation gas, and others into respective regions of the processing container 1, thereby forming a film on each rotating substrate W. Specifically, the source gas discharged in a source gas processing space P1 where the source gas nozzle 31N is disposed adheres to each substrate W. Then, the reaction gas discharged in a reaction gas processing space P2 where the reaction gas nozzle 32N is disposed reacts with the source gas adhered to the substrate W, thereby forming a desired film. Further, in a plan view, the processing container 1 may separate the source gas processing space P1 and the reaction gas processing space P2 by supplying the separation gas to the separation space H.

### <Configuration of Heating Unit 7>

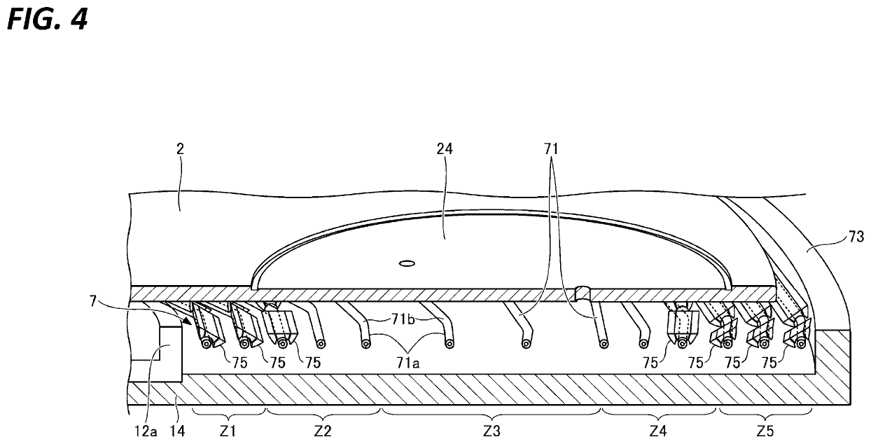

Next, a configuration of the heating unit 7 of the substrate processing apparatus 100 will be described with reference to FIG. 1 and FIGS. 4 to 6. The heating unit 7 includes a plurality of heater wires 71 provided in the bottom portion 14 of the processing container 1 in the radial direction, a cover 72 provided between the respective heater wires 71 and the rotary table 2, and an outer peripheral support 73 that supports the cover 72 at the outer periphery of the heating unit 7. Furthermore, the heating unit 7 is provided with a lens member 75 at a position adjacent to an appropriate one of the plurality of heater wires 71. In FIG. 4, the cover 72 is omitted for ease of understanding of the drawing.

Each heater wire 71 is supplied with electric power from a heating control module (not illustrated) based on a command from the control unit 90, so that a wire body itself is heated and transmits radiant heat to the periphery. As the heater wire 71, for example, a carbon wire heater may be used. The carbon wire heater may adopt carbon fibers, or may adopt graphite. However, the heater wire 71 is not limited to carbon, and may instead employ halogen, ceramics, nichrome wires, and others.

Each heater wire 71 repeatedly includes a straight portion 71a extending linearly over a short interval above the bottom portion 14 and a bent portion 71b connecting adjacent straight portions 71a with a slight curvature. Thus, each heater wire 71 exhibits a substantially arcuate polygonal shape, as a whole in a plan view. Further, each heater wire 71 is supported by a support portion 71c protruding vertically upward from the bottom portion 14, thereby extending substantially parallel to the upper surface of the bottom portion 14 at a position spaced apart from the upper surface. The end of each heater wire 71 exposed on the bottom portion 14 is inserted into, for example, the bottom portion 14 via the support portion 71c, and is electrically connected to a wiring (not illustrated) inside the bottom portion 14. This wiring is connected to the heating control module provided outside the processing container 1.

The heating unit 7 forms, as a whole, substantially circular lines by arranging the plurality of arcuate heater wires 71 with circumferential intervals at the same radial position of the bottom portion 14, and arranges these substantially circular lines concentrically with different radial positions centered on the bottom portion 14. The concentrically arranged heater wires 71 are arranged so as to span each substrate W placed in the placement recess 24 of the rotary table 2 in the radial direction, so that all of the heater wires 71 collectively heat each substrate W.

Further, the heating unit 7 may be configured to enable independent heating for each of a plurality of zones Z1 to Z5 in the radial direction of the processing container 1 and the rotary table 2. For example, the heating unit 7 is divided, in order from the center of the rotary table 2 toward the radial outside, into an inner zone Z1, a sub-inner zone Z2, a middle zone Z3, a sub-outer zone Z4, and an outer zone Z5. However, the number of zones and the division positions are not particularly limited, and there may be four or fewer zones, or six or more zones.

Each of the zones Z1 to Z5 represents a ring shape encircling (concentrically) the same radial position inside the processing container 1. Each of the zones Z1 to Z5 performs heating by one or more heater wires 71 disposed therein. The heater wires 71 disposed in the same zone Z1 constitute a group to which the same electric power is supplied from the heating control module. The same applies to the zones Z2 to Z5. By adjusting the electric power for each of the zones Z1 to Z5 in this way, the heating unit 7 may enhance the in-plane uniformity of the temperature of each substrate W placed on the rotary table 2.

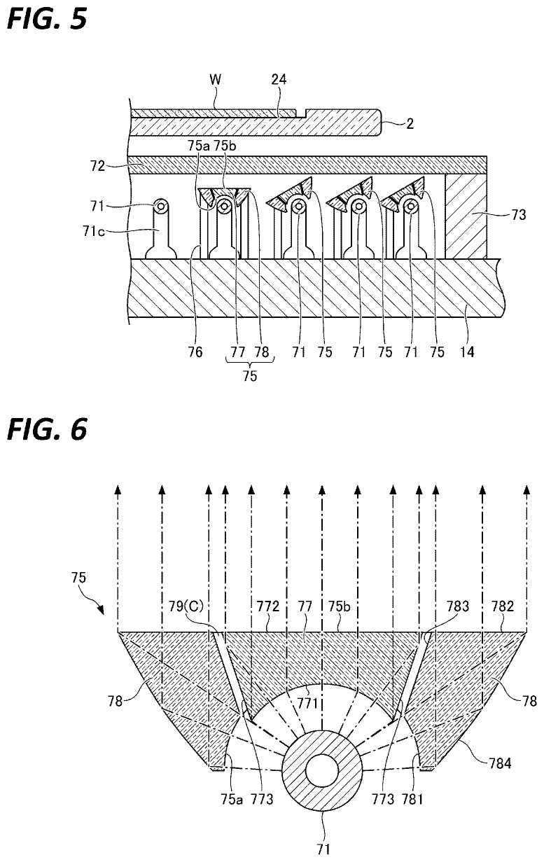

As illustrated in FIGS. 1 and 5, the cover 72 of the heating unit 7 is formed as an annular plate that bridges between the upper end of the protrusion 12a and the outer peripheral support portion 73. That is, the heater wires 71 of the heating unit 7 are accommodated respectively in a space surrounded by the bottom portion 14, the protrusion 12a, the cover 72, and the outer peripheral support portion 73. As described above, the purge gas is supplied from the purge gas supply pipe 74 into the space. Thus, the intrusion of processing gases (source gas and reaction gas) into the space is prevented, and deterioration of the heater wire 71 and the lens member 75 is prevented.

The cover 72 may be made of a material having heat resistance capable of withstanding high temperatures and transparency capable of readily transmitting radiant heat from the respective heater wires 71. For example, quartz having transparency may be used as the material of the cover 72.

Further, the lens member 75 is installed on a part of the heater wire 71 among the respective heater wires 71 of the heating unit 7. The lens member 75 is disposed so as to cover the upper side of the corresponding heater wire 71, and functions to transmit and condense radiant heat, which is electromagnetic waves emitted from the heater wire 71. The material of the lens member 75 may also be quartz having transparency, similar to the cover 72.

The lens member 75 has a semicircular inner peripheral surface 75a on the lower surface side facing the heater wire 71 and a flat surface 75b on the opposite side (e.g., an upper surface side) of the semicircular inner peripheral surface 75a. The lens member 75 is positioned close to the heater wire 71 so that the upper half of the heater wire 71 enters a space surrounded by the semicircular inner peripheral surface 75a. For example, the lens member 75 is supported by a plurality of lens supports 76 installed on the bottom portion 14, thereby being positioned at an equal distance from the outer peripheral surface of the heater wire 71.

Further, the lens member 75 according to the embodiment is formed in a multi-lens structure in which a plurality of components are combined. Specifically, the lens member 75 includes a center condenser 77 positioned at a central portion, and a pair of side condensers 78 respectively positioned on both sides of the center condenser 77. The center condenser 77 and the pair of side condensers 78 have different refractive indices from each other. For example, the center condenser 77 and the pair of side condensers 78 are formed to have appropriately different refractive indices due to differences in the amount or type of additives added to quartz.

A clearance C may be interposed between the center condenser 77 and the pair of side condensers 78 to separate them. For example, the lens member 75 may maintain a mutual positional relationship between the center condenser 77 and the pair of side condensers 78 by a plurality of protruding portions 79, which protrude from the side surface of either the center condenser 77 or the pair of side condensers 78 and come into contact with the side surface of the other, thereby defining the clearance C. However, since the lens member 75 may change the direction of radiant heat at the boundary between the center condenser 77 and the pair of side condensers 78 as long as the refractive index of the center condenser 77 and the refractive index of the pair of side condensers 78 are different, the clearance C may not be required. Alternatively, in a configuration in which the clearance C is provided between the center condenser 77 and the pair of side condensers 78, the refractive index of the center condenser 77 and the refractive index of the side condensers 78 may be the same. This is because the clearance C itself functions as a boundary that changes the refractive index of radiant heat.

The center condenser 77 includes a heater-facing surface 771 having an arcuate cross-sectional shape that constitutes the semicircular inner peripheral surface 75a, an opposite surface 772 having a linear cross-sectional shape that constitutes the flat surface 75b, and a pair of inclined side surfaces 773 extending between both ends of the heater-facing surface 771 and both ends of the opposite surface 772. The pair of inclined side surfaces 773 are inclined such that the spacing therebetween widens from the heater-facing surface 771 toward the opposite surface 772.

Thus, radiant heat emitted from the top of the heater wire 71 enters the center condenser 77 from the heater-facing surface 771. The center condenser 77 may refract the radiant heat by the heater-facing surface 771 or the pair of inclined side surfaces 773, and emit the radiant heat in a direction (normal direction) perpendicular to the opposite surface 772. Then, the radiant heat emitted from the opposite surface 772 travels linearly in parallel.

Each of the pair of side condensers 78 includes a heater-facing surface 781 having an accurate cross-sectional shape that constitutes the semicircular inner peripheral surface 75a, an opposite surface 782 having a linear cross-sectional shape that constitutes the flat surface 75b, an inner side surface 783 facing the inclined side surface 773 of the center condenser 77, and an outer side surface 784 that constitutes the side surface of the lens member 75. The inner side surface 783 is inclined so as to be parallel to the inclined side surface 773. The outer side surface 784 is inclined while bulging slightly in an arcuate shape.

The lower end of each of the pair of side condensers 78 (the boundary between the heater-facing surface 781 and the outer side surface 784) is positioned near a vertically intermediate portion of the heater wire 71. Thus, radiant heat emitted from the top to the vertically intermediate portion of the heater wire 71 enters the pair of side condensers 78 from the heater-facing surface 781. The pair of side condensers 78 may refract the radiant heat by the outer side surface 784 and emit the radiant heat in a direction perpendicular to the opposite surface 782 (e.g., a normal direction). Then, the radiant heat emitted from the opposite surface 782 travels linearly in parallel.

In this way, the lens member 75 may direct the radiant heat emitted from the upper half of the heater wire 71 in parallel along the normal direction of the flat surface 75b by combining the center condenser 77 and the pair of side condensers 78. As a result, it is possible to stably apply beams of radiant heat to the substrate W positioned vertically above the lens member 75.

Further, as illustrated in FIG. 4, the lens member 75 is formed to have a length corresponding to the straight portion 71a of the heater wire 71 in the direction in which the heater wire 71 extends. That is, the lens member 75 is provided so as to overlap the straight portion 71a of the heater wire 71, but is not provided at the bent portion 71b of the heater wire 71. Therefore, the lens member 75 may be easily formed as a component in which the center condenser 77 and the pair of side condensers 78 are linearly continuous with the same cross-sectional shape. The heating unit 7 may use this component (e.g., lens members 75) in a plurality to cover most of each heater wire 71 extending in a substantially arcuate shape.

In the heating unit 7, the above-described lens member 75 is provided for only some of the plurality of heater wires 71 arranged in the radial direction of the bottom portion 14. Here, each substrate W placed on the rotary table 2 is subject, during substrate processing, to effects such as the rotation of the rotary table 2, the supply of gases from the gas supply 30, and the exhaust of gases through the exhaust ports 61, which may result in temperature nonuniformity. For example, the center side of the rotary table 2 is affected by the inflow of the separation gas supplied from the separation gas supply pipe 51 (see, e.g., FIG. 1). Therefore, the temperature of each substrate W tends to decrease more easily at the center side of the rotary table 2. Further, for example, the outer peripheral side of the rotary table 2 is affected by various gases to be discharged from the processing container 1 through the exhaust ports 61. Therefore, the temperature of each substrate W also tends to decrease at the outer peripheral side of the rotary table 2.

The heating unit 7 may independently adjust the temperature along the radial direction of the rotary table 2 by the plurality of pre-divided zones Z1 to Z5. However, the substrate processing apparatus 100 may not sufficiently compensate for the temperature decrease of the substrate W at the center side or the outer peripheral side of the rotary table 2 by simply increasing the temperature of the zone Z1 or the zone Z5 relative to the other zones depending on the content of substrate processing such as an increase in the amount of gas supplied.

From this, in the heating unit 7 according to the embodiment, to increase the amount of heat at the center side of the rotary table 2, the lens member 75 is installed on all of the heater wires 71 in the zone Z1 and on some of the heater wires 71 in the zone Z2. Further, in the heating unit 7, to increase the amount of heat at the outer peripheral side of the rotary table 2, the lens member 75 is installed on some of the heater wires 71 in the zone Z4 and on all of the heater wires 71 in the zone Z5.

In particular, as illustrated in FIG. 5, each heater wire 71 in the zone Z4 is positioned to overlap the substrate W placed on the rotary table 2 in the vertical direction. Therefore, the lens member 75 installed on the heater wire 71 in the zone Z4 is adjusted in posture such that the flat surface 75b is aligned in the horizontal direction (parallel to the rotary table 2).

Meanwhile, each heater wire 71 in the zone Z5 is positioned outside (so as not to overlap) the substrate W placed on the rotary table 2 in the vertical direction. Therefore, the lens member 75 installed on the heater wire 71 in the zone Z5 is adjusted in posture such that the flat surface 75b is inclined relative to the horizontal direction. The inclination angle of the flat surface 75b relative to the horizontal direction may be appropriately adjusted according to a positional relationship with the substrate W. For example, in the embodiment, the inclination angle is set to 30°. Accordingly, the lens member 75 installed on the heater wire 71 in the zone Z5 may direct radiant heat toward the vicinity of the outer periphery of the rotary table 2 and toward the outer peripheral side of the substrate W.

Similarly, the lens member 75 installed on each heater wire 71 in the zone Z1 also has an adjusted inclination angle, which allows this lens member 75 to direct radiant heat around the center of the substrate W. Furthermore, each heater wire 71 in the zone Z2 is positioned so as to overlap the substrate W in the vertical direction, so that the lens member 75 is adjusted in posture such that the flat surface 75b is horizontal.

### <Substrate Processing Method>

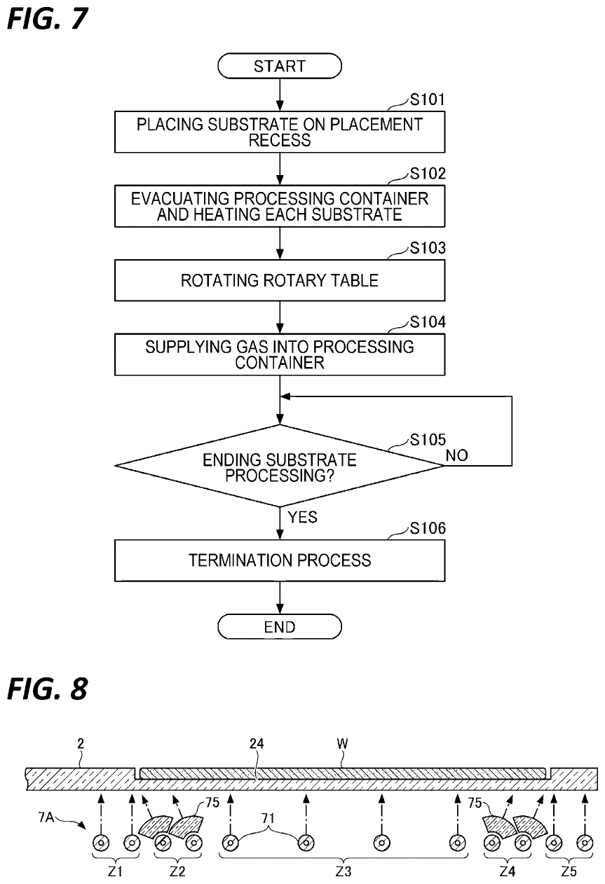

The substrate processing apparatus 100 according to the embodiment is basically configured as described above, and the operation (e.g., a substrate processing method) thereof will be described below with reference to FIG. 7.

During a substrate processing, the control unit 90 of the substrate processing apparatus 100 first controls the substrate processing apparatus 100 and the transport robot 16A to sequentially place the substrates W on five placement recesses 24 of the rotary table 2 (step S101).

Subsequently, the control unit 90 controls the vacuum pump 64 to discharge gases from the processing container 1, thereby evacuating the processing container 1, and controls the heating unit 7 to heat each substrate W (step S102). At this time, the temperature control module connected to each heater wire 71 supplies electric power to each zone Z1 to Z5 based on instructions from the control unit 90, thereby adjusting the temperature of each substrate W to a target temperature.

Then, the control unit 90 controls the driving unit 23 to rotate (revolve) the rotary table 2 at a target speed (step S103). The substrate processing apparatus 100 maintains the target speed of the rotary table 2 even during a substrate processing.

Furthermore, the control unit 90 controls the gas supply 30 to supply gases (e.g., source gas, reaction gas, and separation gas) into the processing container 1, thereby performing a substrate processing on each substrate W (step S104). Thus, each substrate W rotates inside the processing container 1 while an appropriate film is formed on the surface of the substrate.

During the substrate processing, the heating unit 7 controls the electric power supplied to each heater wire 71 via the temperature control module so that the temperature of each substrate W reaches the target temperature. At this time, each lens member 7 arranged in the zones Z1, Z2, Z4, and Z5 prevents waste of radiant heat emitted from the heater wire 71, and converges the radiant heat on each substrate W at the center side of the rotary table 2 and at the outer peripheral side of the rotary table 2. Accordingly, even when the temperature of each substrate W tends to decrease due to the rotation of the rotary table 2 or the gas flow, the heating unit 7 supplies an increased amount of heat to a region of the substrate where the temperature decreases, thereby enhancing the in-plane uniformity of the temperature of each substrate W.

Further, the control unit 90 determines the end of substrate processing during execution of the substrate processing (step S105). For example, the control unit 90 compares the actual substrate processing period with a target period set in the substrate processing recipe, and determines the end of substrate processing when the actual period reaches the target period.

When the control unit 90 determines that substrate processing has been completed, the controller unit 90 performs a termination process to end the substrate processing (step S106). In the termination process, stopping of the supply of gases from the gas supply 30, stopping of the rotation of the rotary table 2, and stopping of heating by the heating unit 7 are performed. Further, after the end of substrate processing, the substrate processing apparatus 100 cooperates with the transport robot 16A to perform the reverse of step S101, thereby unloading each substrate W from the rotary table 2 to the outside of the processing container 1.

The substrate processing apparatus 100 described above may direct the radiant heat of the heater wire 71 in a desired direction by providing the heating unit 7 with the lens member 75. Thus, in a substrate processing, it is possible to increase the amount of heat supplied to a location where the temperature of each substrate W tends to decrease. As a result, the substrate processing apparatus 100 may enhance the in-plane uniformity of the temperature of the substrate W, and enhance the in-plane uniformity of substrate processing.

The substrate processing apparatus 100 and the substrate processing method according to the embodiment are not limited to the above-described embodiment and may take various modifications. For example, the substrate processing performed by the substrate processing apparatus 100 is not limited to film formation. Examples of other substrate processing may include etching, cleaning, modification, and ashing.

Further, the substrate processing apparatus 100 is configured to cause only revolution of each substrate W placed on the rotary table 2, but may also be an apparatus that performs rotation (e.g., spin) of each substrate W in addition to revolution. Alternatively, the substrate processing apparatus 100 is configured to heat a plurality of substrates W on the rotary table 2, but is not limited thereto, and may be a single-wafer type apparatus in which one substrate W is placed on a substrate support and subjected to a substrate processing. Even in this case, the substrate processing apparatus may be configured such that the heating unit 7 for heating the substrate W is provided inside a substrate support, and the lens member 75 is installed on the heater wire 71 of the heating unit 7.

Furthermore, in the heating unit 7, the heater wire 71 may be curved without having the straight portion 71a and the bent portion 71b, and the lens member 75 may also be formed as a continuous member following the curvature of the heater wire 71. Further, the lens member 75 according to the embodiment is supported by the lens supports 76 protruding from the bottom portion 14, but is not limited thereto. For example, the lens member 75 may be supported by a support (not illustrated) protruding from the cover 72. Alternatively, the lens member 75 may be integrally formed with the cover 72 so that the radiant heat from the heater wire 71 is transmitted through both the cover 72 and the lens member 75.

As illustrated in a first modification of FIG. 8, a heating unit 7A may be configured such that the lens member 75 is not provided for each heater wire 71 in the zones Z1 and Z5, but is provided for each heater wire 71 in the zones Z2 and Z4. In this case, the posture (e.g., an inclination angle) of the lens member 75 in the zone Z2 is adjusted to direct radiant heat toward the center of the rotary table 2. Further, the posture of the lens member 75 in the zone Z4 is adjusted to direct radiant heat toward the outer periphery of the rotary table 2. In this way, by installing the lens member 75, it is possible to increase the amount of heat at the center and the outer periphery of the rotary table 2 where the temperature tends to decrease. By promoting the uniformity of the temperature of the rotary table 2, it may be consequently expected that the in-plane uniformity of the temperature of the substrate W placed on the rotary table 2 is improved.

In short, the lens member 75 may be installed on any heater wire 71, such as the heater wire 71 directly below a location where an increase in the amount of heat is desired, or the heater wire 71 positioned close to a location where an increase in the amount of heat is desired. Then, the posture (e.g., an inclination angle) of the lens member 75 may be adjusted to direct radiant heat from the heater wire 71 in an appropriate direction. For example, since the amount of heat tends to increase in a zone where many heater wires 71 are provided, it is possible to reduce the amount of heat in the zone having many heater wires 71 and effectively increase the amount of heat in the periphery by installing the lens member 75 in that zone to direct radiant heat in another direction.

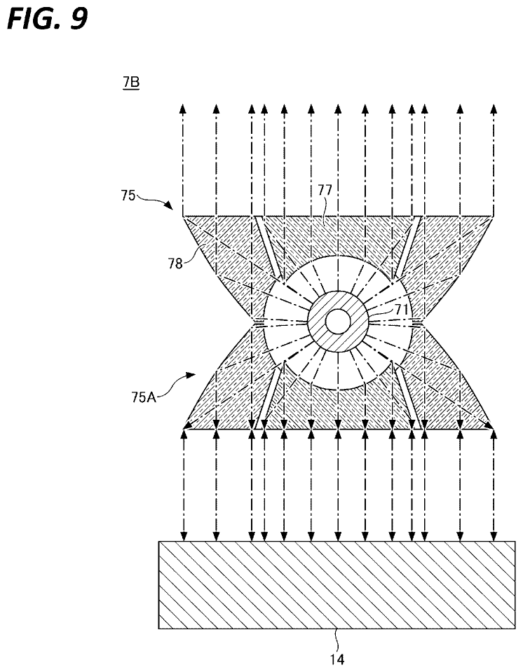

Further, as illustrated in a second modification of FIG. 9, in addition to installing the lens member 75 vertically above the heater wire 71, a heating unit 7B may also be configured to install a lens member 75A vertically below the heater wire 71. That is, the lens member 75A is disposed between the heater wire 71 and the bottom portion 14 of the container body 12.

The lens member 75A directs radiant heat from the lower half of the heater wire 71 in a direction perpendicular to the surface direction of the bottom portion 14. The bottom portion 14, upon receiving the radiant heat in the direction perpendicular to the surface thereof, may reflect the radiant heat as it is (while preventing scattering or irregular reflection) to return the radiant heat to the lens member 75A. The reflected radiant heat returned to the lens member 75A passes through the lens member 75A and is then returned to the heater wire 71. Therefore, the amount of heat in the heater wire 71 increases, and the radiant heat enters the lens member 75 vertically above the heater wire 71, and is emitted from the flat surface 75b of the lens member 75 toward the substrate W.

In this way, the heating unit 7B may appropriately direct the vertically downward radiant heat to the lens member 75 by installing the lens member 75A vertically below the heater wire 71. That is, the heating unit 7B may prevent waste of radiant heat from the heater wire 71 as much as possible, and may further increase the amount of heat imparted to the substrate W.

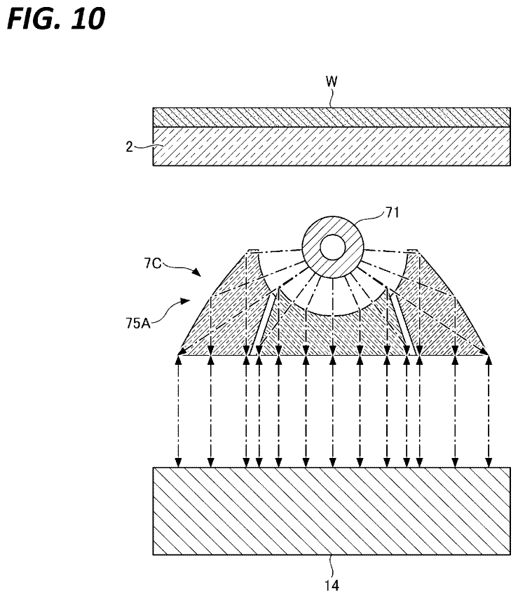

Further, as illustrated in a third modification of FIG. 10, a heating unit 7C may be configured to install the lens member 75A between the bottom portion 14 of the processing container 1 and the heater wire 71, while not installing the lens member 75 vertically above the heater wire 71. Even in this case, as described above, the radiant heat transmitted through the lens member 75A is reflected by the bottom portion 14, thereby increasing the amount of heat in the heater wire 71, and increasing the amount of heat in the substrate W located vertically above the heater wire 71.

### <Technical Ideas and Effects>

The technical ideas and effects of the present disclosure described in the above embodiment will be described below.

In a substrate processing apparatus 100 including a processing container 1, a substrate support (e.g., the rotary table 2) provided in an inside of the processing container 1 and configured to support a substrate W, and a heating unit 7 configured to heat the substrate W supported by the substrate support, the heating unit 7 includes a heater wire 71 configured to transmit radiant heat to a periphery during heating, and a lens member 75, 75A provided at a position adjacent to the heater wire 71, and the lens member 75, 75A is disposed between the substrate support and the heater wire 71 to direct radiant heat toward a direction in which the substrate W is located, and/or disposed between the processing container 1 and the heater wire 71 to direct radiant heat in a direction perpendicular to a surface of the processing container 1.

According to the above, during heating by the heating unit 7, the substrate processing apparatus 100 may increase the amount of heat when heating the substrate W by installing the lens member 75, 75A at a position adjacent to the heater wire 71. That is, the lens member 75 disposed between the substrate support (e.g., the rotary table 2) and the heater wire 71 may direct radiant heat toward a direction in which the substrate W is located, thereby increasing the amount of heat in the substrate W. Further, the lens member 75A disposed between the processing container 1 and the heater wire 71 may direct radiant heat in a direction perpendicular to the surface of the processing container 1, thereby reflecting the radiant heat by the processing container 1 to return it to the heater wire 71. As a result, the amount of heat in the heater wire 71 may be increased, and likewise, the amount of heat in the substrate W may be increased.

Further, the lens member 75, 75A includes a center condenser 77 and a pair of side condensers 78 respectively installed on both sides of the center condenser 77. In this way, by adopting a dual structure of the center condenser 77 and the pair of side condensers 78, the lens member 75 may refract the radiant heat of the heater wire 71 in a desired direction by each of the condensers.

Further, a clearance C is provided between the center condenser 77 and the pair of side condensers 78 to separate them. Thus, the lens member 75, 75A may easily achieve different refractive indices at the boundary between the center condenser 77 and the pair of side condensers 78. Therefore, the lens member 75, 75A may appropriately change the direction of radiant heat by the center condenser 77 and the pair of side condensers 78.

Further, the center condenser 77 and the pair of side condensers 78 are formed of materials having different refractive indices from each other. Thus, the lens member 75, 75A may appropriately refract radiant heat at the boundary between the center condenser 77 and the pair of side condensers 78.

Further, the lens member 75, 75A includes an inner peripheral surface (e.g., the semicircular inner peripheral surface 75a) that faces the heater wire 71 and concentrically surrounds the heater wire 71, and a flat surface 75b provided on an opposite side of the inner peripheral surface. Thus, the lens member 75, 75A may cover a part of the heater wire 71 with the inner peripheral surface, and may further prevent waste of radiant heat emitted from the heater wire 71.

Further, the lens member 75, 75A is installed with the flat surface 75b in an inclined posture with respect to a horizontal direction. Thus, the substrate processing apparatus 100 may direct radiant heat of the heater wire 71 obliquely by the lens member 75, thereby emitting the radiant heat to a desired location.

Further, the substrate support includes a rotary table 2 configured to rotatably support a plurality of substrates W, the heating unit 7 is installed vertically below the rotary table 2, and a plurality of heater wires 71 are provided concentrically along a radial direction of the rotary table 2. Thus, the substrate processing apparatus 100 may stably perform a substrate processing while heating all of the plurality of substrates W by the heating unit 7.

Further, the lens member 75 is installed on the heater wire 71 positioned at an outer peripheral side of the rotary table 2. Thus, the substrate processing apparatus 100 may increase the amount of heat in the substrate W at the outer peripheral side of the rotary table 2 where the temperature tends to decrease, thereby increasing the in-plane uniformity of the temperature of the substrate W.

Further, the lens member 75 is installed on the heater wire 71 positioned at a center side of the rotary table 2. Thus, the substrate processing apparatus 100 may increase the amount of heat in the substrate W at the center side of the rotary table 2 where the temperature tends to decrease, thereby increasing the in-plane uniformity of the temperature of the substrate W.

Further, a second aspect of the present disclosure is a substrate processing method of a substrate processing apparatus 100 including a processing container 1, a substrate support (e.g., the rotary table 2) provided in an inside of the processing container 1 and configured to support a substrate W, and a heating unit 7 configured to heat the substrate W supported by the substrate support, the heating unit 7 including a heater wire 71 configured to transmit radiant heat to a periphery during heating, and a lens member 75 provided at a position adjacent to the heater wire 71, the substrate processing method including (A) placing the substrate W on the substrate support, and (B) heating the heater wire 71 and directing radiant heat in a direction in which the substrate W is located by the lens member 75 disposed between the substrate support and the heater wire 71, and/or directing radiant heat in a direction perpendicular to a surface of the processing container 1 by a lens member 75A disposed between the processing container 1 and the heater wire 71. Even in this case, the substrate processing method may increase the amount of heat when heating the substrate W.

The substrate processing apparatus 100 and the substrate processing method according to the embodiment disclosed herein are illustrative in all respects, and are not restrictive.

According to one aspect, it is possible to increase the amount of heat when heating a substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be restricting, with the true scope and spirit being indicated by the following claims.

What is claimed is:

1. A substrate processing apparatus comprising:
a processing container;
a substrate support provided inside the processing container and configured to support a substrate; and
a heater configured to heat the substrate supported by the substrate support,
wherein the heater includes a heater wire configured to transmit radiant heat to a periphery during heating, and a lens provided at a position adjacent to the heater wire, and
the lens is disposed between the substrate support and the heater wire to direct radiant heat toward a direction in which the substrate is located, and/or disposed between the processing container and the heater wire to direct radiant heat in a direction perpendicular to a surface of the processing container.

2. The substrate processing apparatus according to claim 1, wherein the lens includes a center condenser and a pair of side condensers respectively provided on both sides of the center condenser.

3. The substrate processing apparatus according to claim 2, wherein a clearance is provided between the center condenser and a pair of side condensers to separate the center condenser and a pair of side condensers from each other.

4. The substrate processing apparatus according to claim 2, wherein the center condenser and the pair of side condensers are formed of materials having different refractive indices from each other.

5. The substrate processing apparatus according to claim 1, wherein the lens has an inner peripheral surface that faces the heater wire and concentrically surrounds the heater wire, and a flat surface provided on an opposite side of the inner peripheral surface.

6. The substrate processing apparatus according to claim 5, wherein the lens is disposed with the flat surface in an inclined posture with respect to a horizontal direction.

7. The substrate processing apparatus according to claim 1, wherein the substrate support includes a rotary table configured to rotatably support a plurality of substrates,
the heater is disposed vertically below the rotary table, and
a plurality of heater wires is provided concentrically along a radial direction of the rotary table.

8. The substrate processing apparatus according to claim 7, wherein the lens is disposed on the heater wire positioned at an outer peripheral side of the rotary table.

9. The substrate processing apparatus according to claim 7, wherein the lens is disposed on the heater wire positioned at a center side of the rotary table.

10. A substrate processing method comprising:
providing a substrate processing apparatus including a processing container, a substrate support provided inside the processing container and configured to support a substrate, and a heater configured to heat the substrate supported by the substrate support, the heater including a heater wire configured to transmit radiant heat to a periphery during heating, and a lens provided at a position adjacent to the heater wire;
placing the substrate on the substrate support, and
heating the heater wire, and directing radiant heat in a direction in which the substrate is located by disposing the lens between the substrate support and the heater wire, and/or directing radiant heat in a direction perpendicular to a surface of the processing container by disposing the lens between the processing container and the heater wire.
